(19) United States
(12) Patent Application Publication
(10) Pub. No.: US 2025/0362579 A1
(43) Pub. Date: Nov. 27, 2025

(54) MASK LAYOUT DESIGN METHOD AND MASK MANUFACTURING METHOD INCLUDING THE MASK LAYOUT DESIGN METHOD

(71) Applicant: Samsung Electronics Co., Ltd., Suwon-si (KR)

(72) Inventors: Donggon WOO, Suwon-si (KR); Hungbae AHN, Suwon-si (KR); Junyoung JANG, Suwon-si (KR)

(73) Assignee: Samsung Electronics Co., Ltd., Suwon-si (KR)

(21) Appl. No.: 19/006,422

(22) Filed: Dec. 31, 2024

(30) Foreign Application Priority Data
May 23, 2024 (KR) 10-2024-0067261

(51) Int. Cl. G03F 1/22; G03F 7/00

(52) U.S. Cl. CPC G03F 1/22; G03F 7/0005; G03F 7/70033; G03F 7/70441; G03F 7/70508

(57) ABSTRACT

Provided is a mask layout design method including receiving input data, calculating a forbidden area, and designing an assist pattern disposed within the forbidden area, wherein the calculating of the forbidden area is performed by inverting an illumination system.

### CROSS-REFERENCE TO RELATED APPLICATION

This application is based on and claims priority under 35 U.S.C. § 119 to Korean Patent Application No. 10-2024-0067261, filed on May 23, 2024, in the Korean Intellectual Property Office, the disclosures of which are incorporated by reference herein in their entirety.

### BACKGROUND

The inventive concepts relate to a mask layout design method and a mask manufacturing method including the mask layout design method, and more particularly, to a mask layout design method using an assist pattern and a mask manufacturing method including the mask layout design method.

In manufacturing processes for semiconductor devices, a lithography process is a core process technology that forms a circuit pattern by irradiating light to a photosensitive film applied on a substrate. Meanwhile, as patterns become finer, an optical proximity effect (OPE) (due to the influence between neighboring patterns) occurs during an exposure process. To resolve the problem, an optical proximity correction (OPC) method of suppressing the occurrence of the OPE by correcting a pattern layout on a mask for transferring a pattern is generally employed in a mask manufacturing process.

### SUMMARY

The inventive concepts provide a mask layout design method with reduced dose and a mask manufacturing method including the mask layout design method.

In addition, the technical goals to be achieved by the inventive concepts are not limited to the technical goals mentioned above, and other technical goals may be clearly understood by one of ordinary skill in the art from the following descriptions.

According to an aspect of the inventive concepts, there is provided a mask layout design method including receiving input data, determine a forbidden area based on the input data, and designing an auxiliary pattern disposed within the forbidden area, wherein the determining of the forbidden area is performed by inverting an illumination system.

According to another aspect of the inventive concepts, there is provided a mask layout design method including receiving input data, determining a forbidden area based on the input data, and designing an auxiliary pattern disposed within the forbidden area, wherein the determining of the forbidden area includes clustering an illumination system, inverting the illumination system, searching for an inverted pattern region, and aligning the inverted pattern region.

According to another aspect of the inventive concepts, there is provided a mask manufacturing method including designing a final layout using a mask layout design method, performing optical proximity correction (OPC) on the final layout obtained through the mask layout design method, transmitting the OPC-ed layout data as mask tape-out (MTO) design data, preparing mask data based on the MTO design data, and exposing on a mask substrate based on the mask data to form a mask, wherein the designing of the mask layout includes receiving input data, determining a forbidden area based on the input data, and designing an assist pattern disposed within the forbidden area, and wherein the determining of the forbidden area includes inverting an illumination system.

### BRIEF DESCRIPTION OF THE DRAWINGS

Embodiments of the inventive concepts will be more clearly understood from the following detailed description taken in conjunction with the accompanying drawings in which:

FIG. 1 is a configuration diagram schematically showing extreme ultraviolet (EUV) equipment in relation to a mask layout design method according to at least one embodiment;

FIG. 2 is a diagram showing a mask layout according to at least one embodiment;

FIG. 3 is a flowchart of a mask layout design method according to at least one embodiment;

FIG. 4 is a flowchart of a method of determining a forbidden area according to at least one embodiment;

FIG. 5 is a plot showing a method of clustering illumination systems, according to at least one embodiment;

FIG. 6 is a plot showing a method of inverting illumination systems, according to at least one embodiment;

FIG. 7 is a plot showing a method of searching for an inverted pattern region according to at least one embodiment;

FIG. 8 is a plot showing a method of aligning inverted pattern regions according to at least one embodiment;

FIG. 9 is a diagram illustrating light diffracted by an auxiliary pattern according to at least one embodiment being incident on the pupil of an illumination system;

FIGS. 10 and 11 are diagrams showing the arrangement of auxiliary patterns according to at least one embodiment;

FIG. 12 is a block diagram showing a mask layout design device according to at least one embodiment; and

FIG. 13 is a flowchart of a mask manufacturing method including a mask layout design method, according to at least one embodiment.

### DETAILED DESCRIPTION OF THE EMBODIMENTS

Hereinafter, embodiments of the inventive concepts are described in detail with reference to the accompanying drawings. However, various alterations and modifications may be made to the embodiments and thus, the scope of the disclosure is not limited or restricted to the embodiments. The equivalents should be understood to include all changes, equivalents, and replacements within the idea and the technical scope of the disclosure.

Like reference numerals in the drawings denote like components, and therefore repeat descriptions thereof will be omitted. Some sizes of components in the drawings may be exaggerated for convenience of explanation. In addition, embodiments to be described below are only examples, and various modifications from such embodiments may be possible. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

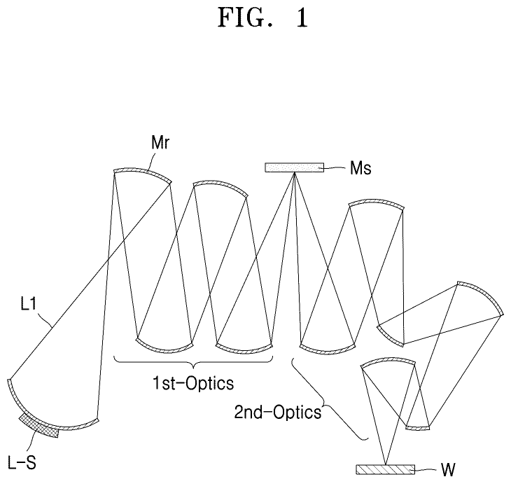

FIG. 1 is a configuration diagram schematically showing extreme ultraviolet (EUV) equipment in relation to a mask layout design method according to at least one embodiment.

To briefly describe the EUV equipment before describing the mask layout design method according to the inventive concepts, the EUV equipment may include an EUV light source L-S, a first optics 1st-Optics, a second optics 2nd-Optics, an EUV mask Ms, and a wafer W. The EUV light source L-S is configured to generate and output EUV light L1 having a high energy density (e.g., within a wavelength range from about 5 nm to about 50 nm). For example, the EUV light source L-S may generate and output the EUV light L1 having a high energy density with a wavelength of about 13.5 nm. In at least some embodiments, the EUV light source L-S may be a plasma-based light source or a synchrotron radiation light source. Here, the plasma-based light source may refer to a light source that generates plasma and uses light emitted by the plasma and may include, e.g., a laser-produced plasma (LPP) light source or a discharge-produced plasma (DPP) light source.

The first optics 1st-Optics may include a plurality of mirrors. For example, the first optics 1st-Optics may include 2 to 5 mirrors Mr. However, the number of mirrors of the first optics 1st-Optics is not limited to 2 to 5. The first optics 1st-Optics may be referred to as an EUV illumination optics or an EUV illumination system. Therefore, in a method of configuring an EUV illumination system according to the present embodiment, the EUV illumination system may correspond to the first optics 1st-Optics. However, according to some embodiments, the EUV illumination system may be used as a collective term including the EUV light source L-S, the first optics 1st-Optics, and the second optics 2nd-Optics.

The first optics 1st-Optics is configured to transmit the EUV light L1 from the EUV light source L-S to the EUV mask Ms. For example, the EUV light L1 from the EUV light source L-S may be made incident to the EUV mask Ms on a mask stage through reflection by the mirrors Mr in the first optics 1st-Optics. Meanwhile, the first optics 1st-Optics may form the EUV light L1 to have a curved slit-like shape and make the EUV light L1 incident on the EUV mask Ms. Here, the curved slit-like shape of the EUV light L1 may mean a parabolic 2-dimensional curve on the XY plane.

According to at least one embodiment, the EUV illumination system may include a plurality of point sources. Here, an EUV point source is the smallest unit that may be individually turned on/off and may be formed by segmenting the EUV illumination system.

The EUV mask Ms is configured to reflect the EUV light L1 incident through the first optics 1st-Optics and to make the EUV light L1 incident on the second optics 2nd-Optics. For example, the EUV mask Ms may reflect the EUV light L1 from the first optics 1st-Optics, structure the EUV light L1 according to the shape of a pattern formed by a reflective multilayer film and an absorption layer on a substrate, and make the EUV light L1 incident on the second optics 2nd-Optics. The EUV light L1 may be structured by including at least secondary diffracted light based on a pattern on the EUV mask Ms. The structured EUV light L1 may be incident on the second optics 2nd-Optics while holding information in the form of the pattern on the EUV mask Ms and may be projected onto an EUV exposure target (e.g., the wafer W), through the second optics 2nd-Optics. The second optics 2nd-Optics may be referred to as an EUV projection optics. The second optics 2nd-Optics may include a plurality of mirrors. For example, the second optics 2nd-Optics may include 4 to 8 mirrors. However, the number of mirrors of the second optics 2nd-Optics is not limited to 4 to 8.

The EUV mask Ms may be placed on and supported by a mask stage. The mask stage is configured to move in order to adjust the relative position of the EUV mask Ms. For example, as the mask stage moves, the EUV mask Ms may be moved in the first horizontal direction (X direction), the second horizontal direction (Y direction), and/or the vertical direction (Z direction) and/or may be rotated around the X axis, the Y axis, and/or the Z axis. Similarly, the wafer W subject to EUV exposure may be placed on and supported by a wafer stage. The wafer stage may be configured to move in order to adjust the relative position of the wafter W. For example, as the wafer stage moves, the wafer W may be moved in the first horizontal direction (X direction), the second horizontal direction (Y direction), and/or the vertical direction (Z direction) and/or may be rotated around the X axis, the Y axis, and/or the Z axis. For example, the mask stage may include and/or be attached to one or more, e.g., motors, actuators, pistons, pullies, rails, etc.

In FIG. 1, the direction parallel to the main surface of the wafer W may be defined as the horizontal direction (X direction and/or Y direction), and the direction perpendicular to the horizontal direction (X direction and/or Y direction) may be defined as the vertical direction (Z direction).

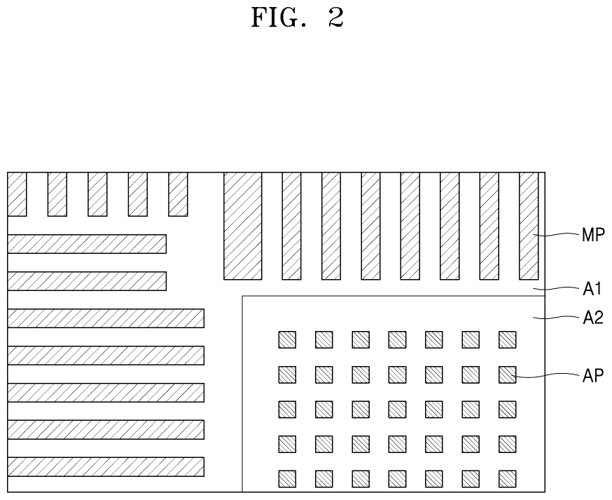

FIG. 2 is a diagram showing a mask layout according to at least one embodiment.

Referring to FIG. 2, the mask layout may include a first region A1 where a main pattern MP is disposed and a second region A2 where an auxiliary pattern AP is disposed. According to at least one embodiment, the mask layout may be referred to as including a full-shot layout.

Here, the full-shot layout may refer to a layout of patterns of an entire mask to be transferred to the wafer W through one shot in an exposure process for manufacturing a semiconductor device. In this specification, data of a full-shot layout may refer to data of a layout of patterns, and the patterns may include a cell pattern and a core pattern.

The main pattern MP may include a wafer image and/or a target image to be transferred onto the wafer W. Also, the auxiliary pattern AP may include a pattern added for reliable image transfer of the main pattern MP. According to at least one embodiment, the auxiliary pattern AP may not be transferred onto the wafer W later.

Although FIG. 2 shows an example in which each of the first region A1 and the second region A2 has a polygonal shape, the inventive concepts is not limited thereto, and, more specifically, each of the first region A1 and the second region A2 may have various shapes.

According to at least one embodiment, the first region A1 may include a core region (or peripheral region), and the second region A2 may include a cell region. According to another embodiment, the first region A1 may include a cell region, and the second region A2 may include a core region. Here, the cell region may be a region where a cell pattern is disposed, and the core region may be a region where a core pattern is disposed. However, the above-stated examples are merely example embodiments, and the first region A1 and/or the second region A2 may include various regions.

In at least one example, in the process of transferring a full-shot layout including the bit line pad (BLP) layer of a dynamic random-access memory (DRAM), when a metal organic resist (MOR) is used as a resist, a separate process for separately generating a cell pattern and a core pattern may be applied. Therefore, in the process of transferring a core pattern (or a cell pattern), the core pattern needs not to be transferred to the wafer W in the cell region (or core region). Therefore, in the process of transferring a core pattern (or cell pattern), the auxiliary pattern AP is applied to reduce a process dose.

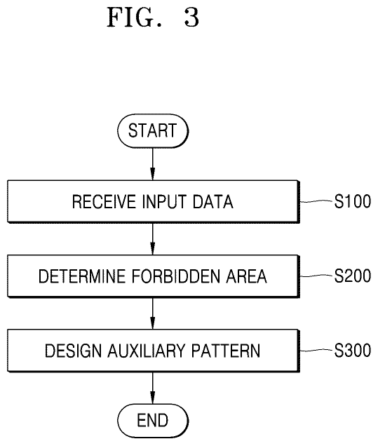

FIG. 3 is a flowchart of a mask layout design method according to at least one embodiment. Descriptions of FIG. 3 will be given below with reference to FIGS. 1 and 2.

Referring to FIG. 3, input data may first be received (operation S100). The input data may include illumination system data. Also, the input data may include information regarding the first region A1 where the main pattern MP is disposed and/or the second region A2 where the auxiliary pattern AP is disposed.

According to at least one embodiment, the input data may include an illumination source map. The illumination system data may include the location of an illumination system. According to at least one embodiment, the illumination system may include a plurality of point sources.

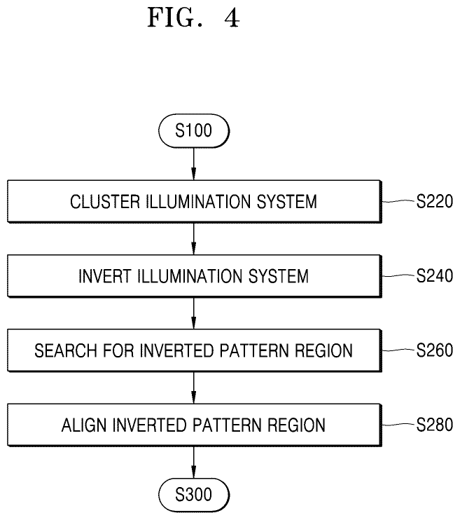

Afterwards, a forbidden area may be determined (e.g., calculated, look up table accessed, etc.) (operation S200). A pattern disposed in the forbidden area may be a region not to be transferred to the wafer W later. Therefore, when the auxiliary pattern AP is formed in the forbidden area, the auxiliary pattern AP may not be transferred to the wafer W. The process of determined the forbidden area will be described with reference to FIGS. 4 to 9.

FIG. 4 is a flowchart of a method of determining a forbidden area according to at least one embodiment.

Referring to FIG. 4, first, illumination systems may be clustered (operation S220). Clustering may include clustering illumination systems adjacent to one another. According to at least one embodiment, the clustering may include determining the center sigma of clustered illumination system. Here, the center sigma may refer to the coordinates of the center of clustered illumination systems. Also, operation S220 may include determination of the number of clustered illumination systems.

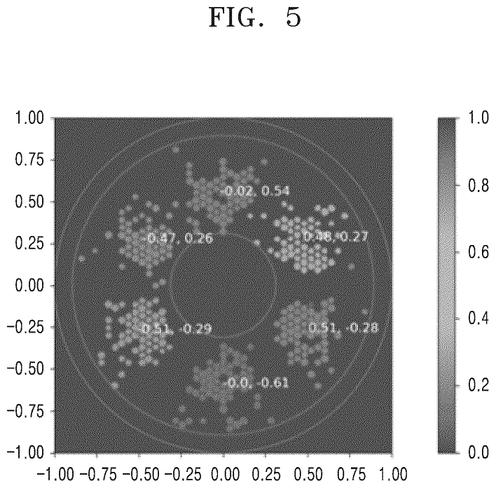

According to at least one embodiment, the clustering may include agglomerative clustering. However, the inventive concepts are not limited thereto, and various methods for clustering illumination systems may be selected. The process of clustering illumination systems will be described below with reference to FIG. 5.

FIG. 5 is a plot showing a method of clustering illumination systems, according to at least one embodiment. In FIG. 5, the horizontal axis represents relative coordinates in the first horizontal direction (X direction), and the vertical axis represents relative coordinates in the second horizontal direction (Y direction). In FIG. 5, the (0, 0) coordinate may be the center of a pupil circle of the illumination system.

Referring to FIG. 5, the illumination systems may be clustered into a plurality of different clusters. The coordinates of the center sigma of each cluster are shown in the drawing. As described above, the center sigma may refer to the coordinates of the center of each cluster. As will be described in detail later, the pitch of the auxiliary pattern AP may be calculated based on the center sigma.

Although FIG. 5 shows that the illumination systems are clustered into six different clusters, this is merely an example, and the inventive concepts are not limited thereto. For example, the illumination systems may be clustered into five or fewer clusters and/or may be clustered into seven or more clusters.

In FIG. 1, the direction parallel to the pupil plane of the illumination system may be correspond to the horizontal direction (X direction and/or Y direction), and the direction perpendicular to the horizontal direction (X direction and/or Y direction) may correspond to the vertical direction (Z direction).

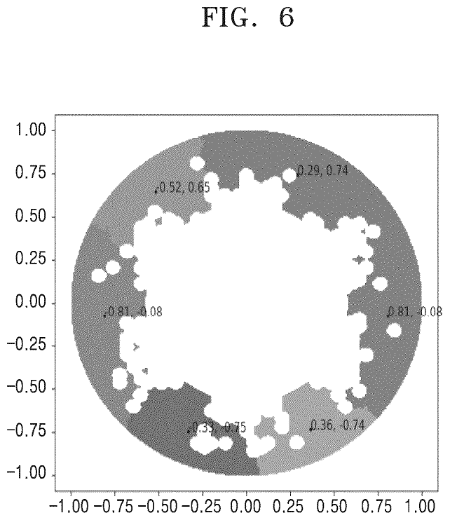

Referring back to FIG. 4, after the illumination systems are clustered (operation S220), the illumination systems may be inverted (operation S240). Inverting the illumination system may include inverting the operation of each unit light source (e.g., a point source). For example, inverting the illumination system may include turning off each point source that is turned on and turning on each point source that is turned off. Also, after illumination systems are inverted, inverted illumination systems may be clustered. The inversion of the illumination system will be described with reference to FIG. 6.

FIG. 6 is a plot showing a method of inverting illumination systems, according to at least one embodiment. In FIG. 6, the horizontal axis represents relative coordinates in the first horizontal direction (X direction), and the vertical axis represents relative coordinates in the second horizontal direction (Y direction). In FIG. 6, the (0, 0) coordinate may be the center of a pupil circle of the illumination system.

Referring to FIG. 6, inverted illumination systems may be clustered based on an average distance. The process of clustering based on an average distance may include clustering based on similarity between data points. For example, according to at least one embodiment, data points with the shortest average distance may be assigned to the same cluster. Also, the center sigma values of each cluster are shown in FIG. 6. Later, alignment of inverted pattern regions may be performed based on the center sigma values of clustered inverted illumination systems.

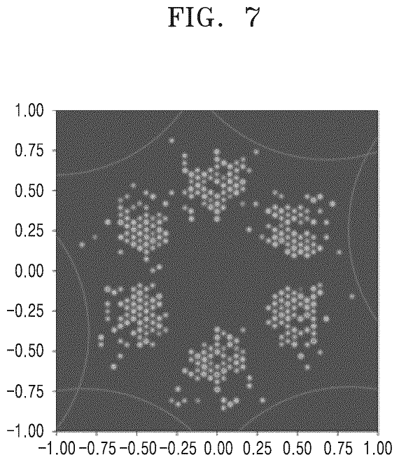

Referring back to FIG. 4, after the illumination system is inverted (operation S240), an inverted pattern region may be searched for (e.g., determined calculated, look up table accessed, etc.) (operation S260). The inversion pattern region is a region to be transferred onto the wafer W under an inverted illumination system, and, in a non-inverted illumination system, the inversion pattern region may be a region that is not transferred onto the wafer W. The inverted pattern region may be a region where a pattern in which first-order component diffracted light is incident on the inverted illumination system is disposed. The inverted pattern region may be the forbidden area described above. Searching for an inverted pattern region will be described with reference to FIG. 7.

FIG. 7 is a plot showing a method of searching for an inverted pattern region according to at least one embodiment. In FIG. 7, the (0, 0) coordinate may be the center of a pupil circle of the illumination system.

Referring to FIG. 7, an inverted pattern region may include a plurality of individual regions. The size of the inversion pattern region may be identical to (and/or substantially similar to) the size of the pupil circle of an illumination system. A plurality of inversion pattern regions may be circular. According to at least one embodiment, the number of clustered illumination systems and the number of inverted pattern regions may be identical to (and/or substantially similar to) each other. According to at least one embodiment, the number of clustered inverted illumination systems and the number of inverted pattern regions may be identical to each other. By changing the positions of each of the inverted pattern regions, a case where an overlapping region between an inverted illumination system and an inverted pattern region is maximized may be searched for.

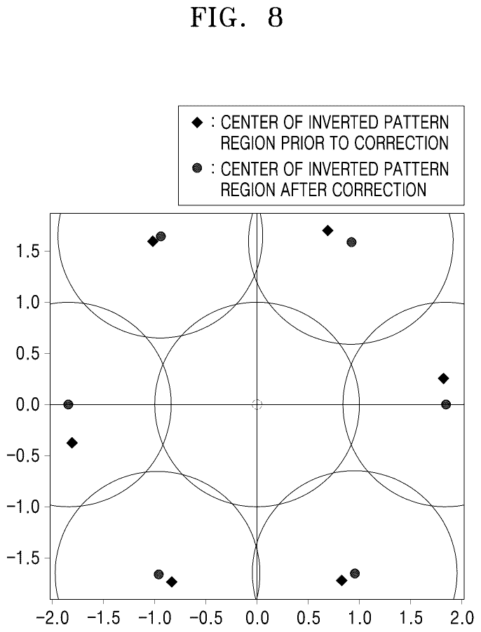

Referring back to FIG. 4, after inversion pattern regions are searched for (operation S260), the inversion pattern regions may be aligned (operation S280). Alignment of an inverted pattern region will be described with reference to FIG. 8.

FIG. 8 is a plot showing a method of aligning inverted pattern regions according to at least one embodiment. In FIG. 8, the diamond shape represents the center of an inversion pattern region before alignment, and the circular shape represents the center of the inversion pattern region after alignment. In FIG. 8, the (0, 0) coordinate may be the center of a pupil circle of the illumination system.

Referring to FIG. 8, inverted pattern regions may be aligned. According to at least one embodiment, the alignment of inverted pattern regions may include placement of the centers of respective inverted pattern regions, such that line segments interconnecting the midpoint of the coordinate plane (e.g., the center of the pupil plane of an illumination system) and centers of respective inverted pattern regions form angles of 0°, 15°, 30°, 45°, 60°, 75° and/or 90° with respect to the horizontal axis and/or the vertical axis. Here, the horizontal axis may be an axis extending in the first horizontal direction (X direction), and the vertical axis may be an axis extending in the second horizontal direction (Y direction).

According to at least one embodiment, inverted pattern regions may be aligned based on the center sigma value of a cluster of inverted illumination systems. The alignment of inverted pattern regions based on the center sigma value of a cluster of inverted illumination system may include placement of the centers of respective inverted pattern regions, such that line segments interconnecting the midpoint of the coordinate plane (e.g., the center of the pupil plane of an illumination system) and centers of respective clusters form angles of 0°, 15°, 30°, 45°, 60°, 75° and/or 90° with respect to the horizontal axis and/or the vertical axis.

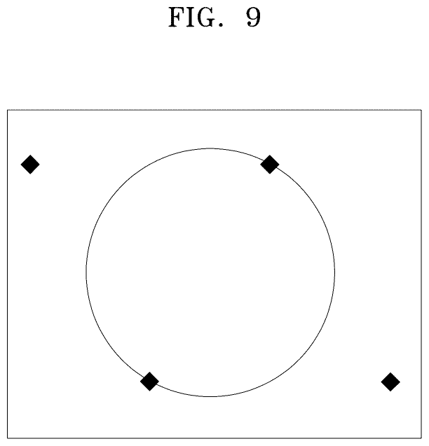

In FIG. 8, the circle centered on the origin of the coordinate plane may be the pupil circle of an illumination system, and the other circles may be inverted pattern regions. Referring to FIG. 9, it may be seen that zero-order light and/or first-order light diffracted by a pattern disposed in an inverted pattern region does not enter the pupil circle of the illumination system.

FIG. 9 is a diagram illustrating light diffracted by an auxiliary pattern according to at least one embodiment being incident on the pupil of an illumination system. In FIG. 9, the (0, 0) coordinate may be the center of a pupil circle of the illumination system. Descriptions thereof will be given with reference to FIG. 2 together.

Referring to FIG. 9, the pupil circle of an illumination system is shown. Zero-order light and/or first-order light diffracted by a pattern disposed in an inverted pattern region may be incident outside the pupil circle of the illumination system. However, as described above, the pattern disposed in the inverted pattern region may not be transferred on the wafer W. Therefore, the auxiliary pattern AP may be disposed in the inverted pattern region to reduce and/or prevent the first-order light from entering the illumination system, and thereby the auxiliary pattern AP may not be transferred to the wafer W.

Referring back to FIG. 3, after the forbidden area is determined (operation S200), the auxiliary pattern AP may be designed (operation S300). Designing of the auxiliary pattern AP may include determining (e.g., calculating, look up table access, etc.) the pitch of the auxiliary pattern AP and selection of an arrangement of the auxiliary pattern AP. As described above, the auxiliary pattern AP may be a pattern that is not to be transferred to the wafer W later. According to at least one embodiment, when first-order light diffracted by the auxiliary pattern AP does not enter the illumination system, the auxiliary pattern AP may not be transferred to the wafer W.

The pitch of the auxiliary pattern AP may be calculated based on the center sigma of a plurality of clusters. Here, the plurality of clusters may be clustered illumination systems. For example, the center sigma may be the center sigma value obtained in operation S220. The pitch of the auxiliary pattern AP may be determined based on Equation 1 below.

$$Pitch = \frac{wavelength / NA}{1 + sigma} \qquad [ Equation 1 ]$$

In Equation 1, Pitch denotes the pitch of the auxiliary pattern AP, wavelength denotes the wavelength of light of the illumination system, NA denotes the numerical aperture of the illumination system, and sigma denotes the distance from the center of the coordinate system to the center sigma of each cluster.

Here, the center of the coordinate system may be the center of the pupil circle of the illumination system. In other words, sigma of Equation 1 may represent the distance from the center of the pupil circle of the illumination system to the center of the plurality of clusters.

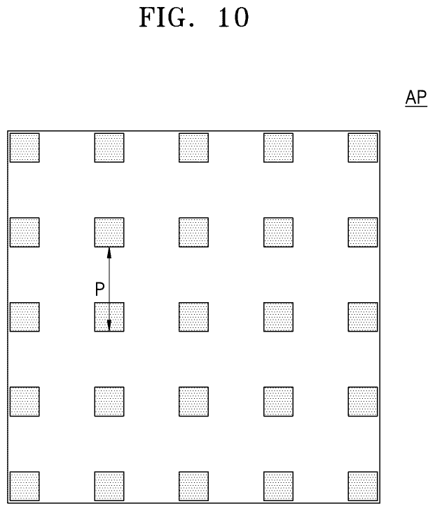

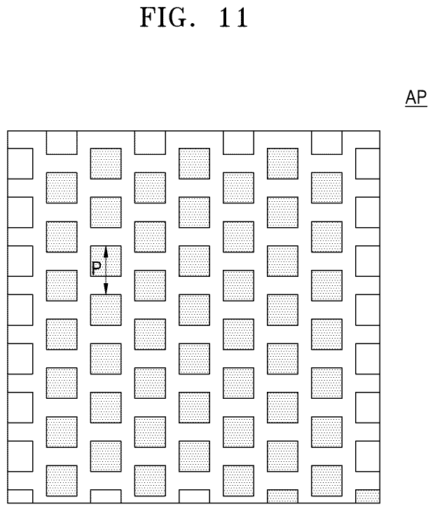

Also, the arrangement of auxiliary patterns AP may be selected based on the arrangement of the illumination system. According to at least one embodiment, the arrangement of the auxiliary patterns AP may be selected based on the number of illumination system clusters and/or the arrangement of the illumination system clusters. According to at least one embodiment, the arrangement of the auxiliary patterns AP may be selected based on the arrangement shape of the inverted pattern region that maximizes the overlapping region with respect to the inverted illumination system. For example, the auxiliary patterns AP may be arranged in a checkerboard-like arrangement and/or a staggered arrangement. The arrangement of the auxiliary patterns AP will be described with reference to FIGS. 10 and 11.

FIGS. 10 and 11 are diagrams showing the arrangement of auxiliary patterns according to at least one embodiment.

FIG. 10 shows an example that the auxiliary patterns AP are arranged in a checkerboard-like arrangement, and FIG. 11 shows an example that the auxiliary patterns AP are arranged in a staggered arrangement. However, the inventive concepts are not limited thereto, and the auxiliary patterns AP may be arranged in various ways and/or may include various shapes.

Since the auxiliary pattern AP is a pattern not to be transferred to the wafer W, when performing a semiconductor process based on the mask layout, the main pattern MP may be transferred to the first region A1, and the auxiliary pattern AP may not be transferred to the second region A2. Later, a process of transferring an additional pattern (e.g., a cell pattern) to the second region A2 may be additionally performed.

The mask layout design method according to the inventive concepts may mitigate and/or prevent a decrease in the critical dimension of the pattern formed in the first region A1 by disposing the auxiliary pattern AP in the second region A2. Also, the mask layout design method according to the inventive concepts arranges the auxiliary pattern AP based on the arrangement of the illumination system, thereby reducing the process dose and improving the process cost.

In at least some embodiments, the mask layout design method may be implemented by processing circuitry such as hardware, software, or a combination thereof configured to perform a specific function. For example, the processing circuitry more specifically may include (and/or be included in), but is not limited to, a central processing unit (CPU), a neural processing unit (NPU), deep learning processor (DLP), an arithmetic logic unit (ALU), a digital signal processor, a microcomputer, a field programmable gate array (FPGA), and programmable logic unit, a microprocessor, application-specific integrated circuit (ASIC), etc.

For example, the processing circuitry may be included in and/or configured to control a semiconductor processing apparatus such that a production of a mask, and/or a subsequent series of processes (e.g., development, etching, cleaning, or the like) are controlled based on a mask layout developed based on the results of mask layout design method. As such, a chip may be produced using a mask manufactured based on results of the mask layout design method.

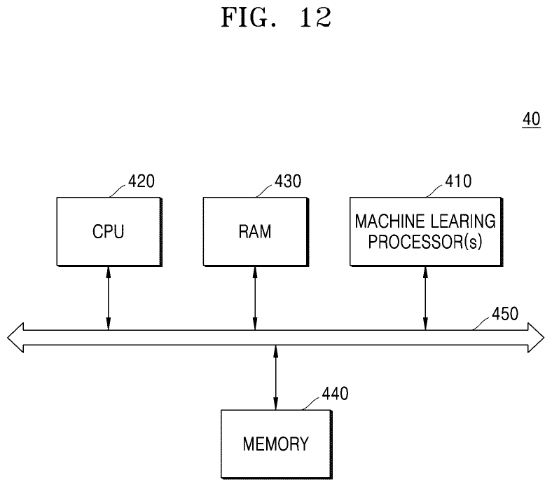

FIG. 12 is a block diagram showing a mask layout design device according to at least one embodiment. Descriptions below will be given with reference to FIGS. 1 to 11 together.

Referring to FIG. 12, a mask layout design device 40 is configured to perform data clustering using a machine learning model. The mask layout design device 40 may include a machine learning processor 410, a CPU 420, a random access memory (RAM) 430, a memory 440, and a bus 450.

According to some embodiments, the mask layout design device 40 may further include other general-purpose components in addition to the components shown in FIG. 12. For example, the mask layout design device 40 may further include an input/output module, a security module, and a power control device, and may further include various types of processors. Also, according to some embodiments, at least one of the components shown in FIG. 12 may be omitted from the mask layout design device 40. The components of the mask layout design device 40 may communicate with one another through the bus 450.

The machine learning processor 410 is configured to infer information from input data by analyzing the input data through machine learning. The machine learning processor 410 may determine a situation or control components of a mounted electronic device based on inferred information. The machine learning processor 410 may be trained, e.g., based on training input data and trained to output data based on the input data. The training data may be labeled and/or unlabeled, and the training may include updating the model of the machine learning processor 410 based on comparisons of the inferred information and results of applying the inferred information in real-world applications. For example, the machine learning processor 410 may be trained to output a determined forbidden area and/or designed auxiliary patterns AP based on inputs including training illumination system data. In at least one embodiment, the machine learning processor 410 may be configured to operate an OPC model. An example OPC model is provided below in further detail.

Also, the machine learning processor 410 may receive input data from the memory 440 and generate output data based on received input data. The machine learning processor 410 may cluster illumination systems and/or cluster inverted illumination systems.

According to at least some embodiments, the mask layout design device 40 may further include an additional processor, which may be configured to cluster illumination systems and/or cluster inverted illumination systems.

The machine learning processor 410 may be implemented with a coprocessor, a digital signal processor (DSP), an application specific integrated circuit (ASIC), a field-programmable gate array (FPGA), a graphics processing unit (GPU), and a neural processing unit (NPU) a tensor processing unit (TPU), a multi-processor system-on-chip (MPSoC), etc.

The machine learning processor 410 may be configured to train (or learn) a machine learning model based on K-means clustering, hierarchical clustering, density-based spatial clustering of applications with noise (DBSCAN), mean shift clustering, and Gaussian mixture models, spectral clustering, K-Medoids clustering, and/or agglomerative clustering. Meanwhile, the types of machine learning models are not limited to the above-stated examples.

The CPU 420 is configured to control the overall operation of the mask layout design device 40. The CPU 420 may include a single core or multi-cores. The CPU 420 may process or execute programs and/or data stored in a storage region like the memory 440 by using the RAM 430.

For example, the CPU 420 may control (or enable) the machine learning processor 410 to execute an application and perform machine learning-based tasks demanded as the application is executed. In at least some embodiments, the CPU 420 may be further configured to control the semiconductor processing apparatus based on the results (e.g., output data) of the machine learning processor 410.

The memory 440 may store illumination system data. The memory 440 may include at least one of a volatile memory and a non-volatile memory. The non-volatile memory includes a read-only memory (ROM), a programmable ROM (PROM), an electrically programmable ROM (EPROM), an electrically erasable and programmable ROM (EEPROM), a flash memory, etc. The volatile memory includes a dynamic RAM (DRAM), a static RAM (SRAM), a synchronous DRAM (SDRAM), a PRAM, an MRAM, an RRAM, an FeRAM, etc. According to some embodiments, the memory 440 may include at least one of a hard disk drive (HDD), a solid state drive (SSD), a compact flash (CF) card, a secure digital (SD) card, a micro secure digital (Micro-SD) card, a mini Secure digital (Mini-SD) card, an extreme digital (xD) card, a memory stick, and/or the like.

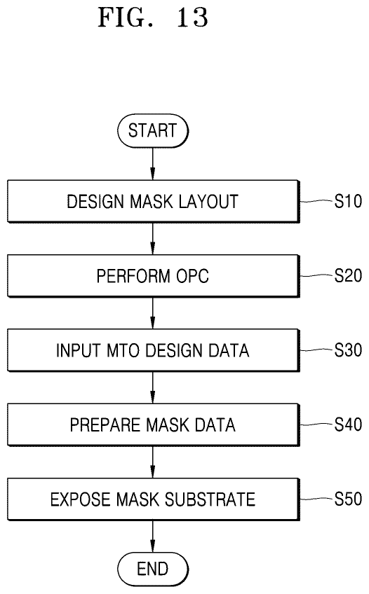

FIG. 13 is a flowchart of a mask manufacturing method including a mask layout design method, according to some embodiments.

Referring to FIG. 13, first, a mask layout is designed (operation S10). The designing of a mask layout may be identical to (and/or substantially similar to) that described for the mask layout design method with reference to FIGS. 3 to 11. In other words, the designing of the mask layout (operation S10) may include reception of the input data of FIG. 3 (operation S100), determining (e.g., calculating, look up table access, etc.) a forbidden area (operation S200), and designing an auxiliary pattern (operation S300). Also, the determining the forbidden area (operation S200) may include clustering of the illumination system of FIG. 4 (operation S220), inversion of the illumination system (operation S240), calculation of an inverted pattern region (operation S260), and alignment of the inverted pattern region (operation S280).

Afterwards, optical proximity correction (OPC) is performed on a final layout obtained by performing the mask layout design method (operation S20). As a pattern on a mask becomes finer, the optical proximity effect (OPE) due to the influence of neighboring patterns to each other occurs during an exposure process. Therefore, the OPC that suppresses the occurrence of the OPE by correcting a mask layout may be performed. The OPC may include the process of generating an optical image regarding a corresponding pattern, generating an OPC model, and obtaining an image or data regarding a mask layout through simulation using the OPC model.

A general explanation of the OPC is as follows. OPCs are roughly divided into two types: a rule-based OPC and a simulation-based (or model-based) OPC. OPC in the mask layout design method according to the present embodiment may be, for example, the model-based OPC. The model-based OPC may be advantageous in terms of time and cost, because only measurement results of representative patterns are used without the need to measure a large number of test patterns. Meanwhile, the OPC method may not only include a method of changing a mask layout, but also include a method of adding sub-lithographic features called as serifs on corners of a pattern or a method of adding SRAFs such as scattering bars.

First, basic data for OPC is prepared. Here, the basic data may include data regarding shapes of patterns of a sample, the locations of the patterns, the type of measurement such as measurement of a space or a line of a pattern, and basic measurement values. Also, the basic data may include information such as a thickness, a refractive index, and a dielectric constant for a photo resist PR and may include a source map regarding the shape of an illumination system. Of course, the basic data is not limited to the above-stated data.

After the basic data is prepared, an optical OPC model is generated. The generation of the optical OPC model may include optimization and/or improvement of a defocus stand (DS) position, a best focus (BF) position, etc. in an exposure process. Also, the generation of the optical OPC model may include generation of an optical image in consideration of the diffraction phenomenon of light or an optical state of an exposure equipment. Of course, the generation of an optical OPC model is not limited to the descriptions given above. For example, the generation of an optical OPC model may include various technical features related to optical phenomena during an exposure process.

After generating the optical OPC model, an OPC model for the PR is generated. The generation of an OPC model for the PR may include optimization of the threshold of the PR. Here, the threshold value of the PR refers to the threshold value at which a chemical change occurs during an exposure process. For example, the threshold value may be given as the intensity of exposure light. The generation of an OPC model for the PR may also include selection of an appropriate model form from among several PR model forms.

Generally, the optical OPC model and the OPC model for the PR are collectively referred to as an OPC model. After the OPC model is generated, simulation is repeatedly performed using the OPC model. The simulation may be performed until certain conditions are satisfied. For example, a root mean square (RMS), an edge placement error (EPE), a reference number of times of repetitions, etc. regarding a CD error may be used as conditions for repeating the simulation. In the mask layout design method according to the present embodiment, OPC layout images or data may be obtained through simulation using the OPC model.

Afterwards, the OPC layout data is transferred to a mask production team as MTO design data (operation S30). In general, MTO may refer to handing over final mask data obtained through an OPC method to the mask manufacturing team to request manufacturing of a mask. Therefore, ultimately, the MTO design data may be substantially identical to the OPC-ed layout data. Such MTO design data may have a graphic data format used in electronic design automation (EDA) software, etc. For example, the MTO design data may have a data format such as Graphic Data System II (GDS2), Open Artwork System Interchange Standard (OASIS), etc.

Thereafter, mask data preparation (MDP) is performed (operation S40). The MDP may include, for example, i) format conversion, called fracturing, ii) augmentation of barcodes for mechanical reading, a standard mask pattern for inspection, a job deck, etc., and iii) automatic and manual verification. Here, a job-deck may refer to generation of a text file regarding a series of instructions such as arrangement information of multiple mask files, a standard dose, and a speed or a method of exposure.

Meanwhile, the format conversion (e.g., fracturing) may refer to a process of dividing MTO design data into respective regions and converting the MTO design data to a format for electron beam exposure equipment. The fracturing may include data manipulation, such as scaling, sizing of data, rotating of data, reflecting a pattern, and inverting colors. During a conversion process through fracturing, data regarding a large number of systematic errors that may occur somewhere during transmission from design data to an image on a wafer may be corrected. The process of correction of data regarding systematic errors is called mask process correction (MPC) and may include, for example, a task for adjusting a line width called CD adjustment and a task for improving pattern placement precision. Therefore, the fracturing may contribute to improving the quality of a final mask and may also be a process that is performed in advance for mask process correction. Here, the systematic errors may be caused by distortions occurring in an exposure process, a mask development and etching process, and a wafer imaging process.

Meanwhile, the MDP may include the MPC. As described above, the MPC refers to a process of correcting errors that occur during an exposure process (e.g., systematic errors). Here, the exposure process may be an overall concept that includes electron beam writing, development, etching, baking, etc. Also, data processing may be performed prior to the exposure process. The data processing is a preprocessing process regarding mask data and may include grammar check for mask data, exposure time prediction, etc. Through the preparation of the mask data, E-beam data to expose a mask substrate may be generated.

After the mask data is prepared, the mask substrate is exposed by using the mask data, e.g., the E-beam data (operation S50). Here, the exposure may refer to, for example, E-beam writing. Here, the E-beam writing may be performed, for example, through a gray writing method using a multi-beam mask writer (MBMW). Also, the E-beam writing may also be performed using variable shape beam (VSB) exposure equipment.

Meanwhile, after the MDP, a process of converting the E-beam data into pixel data may be performed before an exposure process. Pixel data is data directly used for actual exposure and may include data regarding a shape to be exposed and data regarding the dose of an E-beam assigned to each shape. Here, the data regarding a shape may be bit-map data obtained by converting shape data, which is vector data, through rasterization or the like.

After the exposure process, a series of processes may be performed to complete a mask. The series of processes may include, for example, development, etching, and cleaning. Also, a series of processes for manufacturing a mask may include a metrology process, a defect inspection process, or a defect repair process. Also, a pellicle application process may be included. Here, the pellicle application process may refer to a process of attaching pellicles to a mask surface to protect a mask from subsequent contamination during delivery and during the useful life of the mask when it is confirmed that there are no contaminant particles or chemical stains through final cleaning and inspection.

According to at least one embodiment, as described above, a mask may be used to expose (or develop) a metal organic resist. For example, the mask may be used when transferring a pattern onto a metal organic resist. For example, in the process of transferring a full-shot layout including the bit line pad (BLP) layer of a dynamic random-access memory (DRAM), when a metal organic resist (MOR) is used as a resist, a separate process for separately generating a cell pattern and a core pattern is demanded. Therefore, in the process of transferring a core pattern (or a cell pattern), the core pattern needs not to be transferred to the wafer W in the cell region (or core region). In the process of transferring a core pattern (or cell pattern) the auxiliary pattern AP is applied to reduce the process dose.

While the inventive concepts have been particularly shown and described with reference to embodiments thereof, it will be understood that various changes in form and details may be made therein without departing from the spirit and scope of the following claims.

What is claimed is:

1. A mask layout design method comprising:
receiving input data;
determine a forbidden area based on the input data; and
designing an auxiliary pattern disposed within the forbidden area,
wherein the determining of the forbidden area is performed by inverting an illumination system.

2. The mask layout design method of claim 1, wherein the input data comprises illumination system data.

3. The mask layout design method of claim 1, wherein the determining of the forbidden area further comprises clustering the inverted illumination system.

4. The mask layout design method of claim 1, wherein the determining of the forbidden area comprises searching for an inverted pattern region where an overlapping region with the inverted illumination system is maximized.

5. The mask layout design method of claim 1, wherein the designing the auxiliary pattern includes selecting an arrangement shape of the auxiliary pattern based on an arrangement of the illumination system.

6. The mask layout design method of claim 1, wherein the illumination system comprises a plurality of point sources.

7. The mask layout design method of claim 1, wherein the designing the auxiliary pattern includes designing the auxiliary pattern such that the auxiliary patterns include at least one of a checkerboard-like arrangement or a staggered arrangement.

8. A mask layout design method comprising:
receiving input data;
determining a forbidden area based on the input data; and
designing an auxiliary pattern disposed within the forbidden area,
wherein the determining the forbidden area comprises
clustering an illumination system,
inverting the illumination system,
searching for an inverted pattern region, and
aligning the inverted pattern region.

9. The mask layout design method of claim 8, wherein the clustering of the illumination system comprises determining a number of clustered illumination systems and a center sigma value of each of the clustered illumination systems.

10. The mask layout design method of claim 8, wherein the designing of the auxiliary pattern comprises determining a pitch of the auxiliary pattern based on the center sigma value.

11. The mask layout design method of claim 8, wherein the clustering of the illumination system includes an agglomerative clustering.

12. The mask layout design method of claim 8, wherein the inverted pattern region comprises a region in which a pattern in which first-order component diffracted light is incident on the inverted illumination system is disposed under the inverted illumination system.

13. The mask layout design method of claim 8, wherein the searching for the inverted pattern region comprises:
clustering the inverted illumination system; and
determining an inverted pattern region where an overlapping region with a clustered inverted illumination system is maximized.

14. The mask layout design method of claim 13, wherein the clustering of the inverted illumination system is performed based on an average distance between data points.

15. The mask layout design method of claim 8, wherein the inverted pattern region comprises one or more regions, and
each inverted pattern region has a size identical to a size of a pupil circle of the illumination system.

16. A mask manufacturing method comprising:
designing a final layout using a mask layout design method;
performing optical proximity correction (OPC) on the final layout obtained through the mask layout design method;
transmitting the OPC-ed layout data as mask tape-out (MTO) design data;
preparing mask data based on the MTO design data; and
exposing on a mask substrate based on the mask data to form a mask,
wherein the mask layout design method comprises
receiving input data,
determining a forbidden area based on the input data, and
designing an assist pattern disposed within the forbidden area, and
wherein the determining of the forbidden area includes inverting an illumination system.

17. The mask manufacturing method of claim 16, wherein the determining of the forbidden area comprises:
clustering the illumination system;
inverting the illumination system;
searching for inverted pattern regions in the inverted illumination system; and
aligning the inverted pattern regions.

18. The mask manufacturing method of claim 17, wherein in the searching for the inverted pattern region, a number of the clusters is identical to a number of the inverted pattern regions.

19. The mask manufacturing method of claim 16, wherein the designing the mask layout includes designing the mask layout such that the mask layout comprises a main pattern and an auxiliary pattern.

20. The mask manufacturing method of claim 16, wherein the mask is configured to be used to develop a metal organic resist.
